(19) United States
(12) Patent Application Publication
(10) Pub. No.: US 2026/0206347 A1
(43) Pub. Date: Jul. 16, 2026

(54) IMAGE SENSOR

(71) Applicant: Samsung Electronics Co., Ltd., Suwon-si (KR)

(72) Inventors: Jongwoo HONG, Suwon-si (KR); Insung JOE, Suwon-si (KR); Changrok MOON, Suwon-si (KR)

(73) Assignee: Samsung Electronics Co., Ltd., Suwon-si (KR)

(21) Appl. No.: 19/320,679

(22) Filed: Sep. 5, 2025

(30) Foreign Application Priority Data
Jan. 15, 2025 (KR) 10-2025-0006382

(51) Int. Cl. H10F 39/00

(52) U.S. Cl. CPC H10F 39/8063; H10F 39/8053

(57) ABSTRACT

Provided is an image sensor capable of increasing auto dark level compensation (ADLC) performance in an optical black region and increasing the freedom of a metal process. The image sensor includes a substrate including an active pixel region and an optical black (OB) region outside the active pixel region, the active pixel region including a plurality of active pixels arranged in a two-dimensional array structure; a photoelectric conversion element (PD) in the active pixel region and the OB region of the substrate; a spacer layer on the PD; and a meta-optical element (MOE) layer on the spacer layer, the OB region including an ADLC region.

### CROSS-REFERENCE TO RELATED APPLICATION

This application is based on and claims priority under 35 U.S.C. § 119 to Korean Patent Application No. 10-2025-0006382, filed on Jan. 15, 2025, in the Korean Intellectual Property Office, the disclosure of which is incorporated by reference herein in its entirety.

### BACKGROUND

The inventive concepts relate to image sensors, and more particularly, to image sensors including a meta-optical element.

Image sensors are devices that may convert optical information into electrical signals. Image sensors may include a pixel array including a plurality of pixels arranged two-dimensionally. Each pixel may include at least one photodiode. The photodiode may convert incident light into electrical signals. The pixel array may include an active pixel region, which includes active pixels generating an image signal, and an optical black region including reference pixels generating a reference signal at a dark level. Image sensors may refer to the reference signal to process an image signal and generate a final image signal.

### SUMMARY

The inventive concepts provide image sensors capable of increasing auto dark level compensation (ADLC) performance in an optical black region and increasing the freedom of a metal process.

The problems to be solved by the technical ideas of the inventive concepts are not limited to those mentioned above, and the inventive concepts can be clearly understood by those skilled in the art from the description below.

According to some aspects of the inventive concepts, there is provided an image sensor including a substrate including an active pixel region and an optical black (OB) region outside the active pixel region, the active pixel region comprising a plurality of active pixels arranged in a two-dimensional array structure, a photoelectric conversion element (PD) in the active pixel region and the OB region of the substrate, a spacer layer on the PD, and a meta-optical element (MOE) layer on the spacer layer, the OB region including an ADLC region.

According to some aspects of the inventive concepts, there is provided an image sensor including a substrate including an active pixel region and an OB region outside the active pixel region, the active pixel region including a plurality of active pixels arranged in a two-dimensional array structure, a PD arranged in the active pixel region and the OB region of the substrate, a spacer layer on the PD, and an MOE layer on the spacer layer and including a plurality of nano-posts and a dielectric layer arranged between the plurality of nano-posts, the OB region including a dummy region, a drain region, and an ADLC region, the dummy region and the drain region being respectively at opposite sides of the ADLC region in a first direction.

According to some aspects of the inventive concepts, there is provided an image sensor including a first semiconductor chip including a first substrate and a first wiring layer below the first substrate, the first substrate including an active pixel region and an OB region outside the active pixel region, and the active pixel region including a plurality of active pixels are arranged in a two-dimensional array structure in the active pixel region and a second semiconductor chip coupled to the first semiconductor chip, the second semiconductor chip including a second substrate and a second wiring layer on the second substrate, the second substrate including a logic area including logic devices, the first semiconductor chip including a PD arranged in the active pixel region and the OB region of the substrate, a spacer layer on the PD, and an MOE layer on the spacer layer, and the OB region including an ADLC region.

According to some aspects of the inventive concepts, there is provided an image sensor including a pixel area including a substrate including an active pixel region and an OB region outside the active pixel region, the active pixel region comprising a plurality of active pixels arranged in a two-dimensional array structure, a photoelectric conversion element (PD) in the active pixel region and the OB region of the substrate, a spacer layer on the PD, and a meta-optical element (MOE) layer on the spacer layer, the OB region including an ADLC region; a row driver configured to select pixels of the plurality of active pixels and drive the selected pixels of the plurality of active pixels; a mode set register configured to set an operation mode of the image sensor; a ramp signal generator configured to generate a ramp signal; a timing controller configured to control the row driver based on a row control signal and control the ramp signal generator; an analog-to-digital converter (ADC) block configured to convert an output of the pixel area from an analogue signal to a digital image signal; and an image signal processor (ISP) configured to output a final image signal based on the digital image signal.

Further, in some aspects of the inventive concepts, wherein the MOE layer is configured to filter light away from the ADLC region.

### BRIEF DESCRIPTION OF THE DRAWINGS

Example embodiments will be more clearly understood from the following detailed description taken in conjunction with the accompanying drawings in which:

FIG. 1 is a block diagram of an image sensor according to some example embodiments;

FIGS. 2A and 2B are respectively a perspective view and a cross-sectional view of the image sensor of FIG. 1;

FIG. 3 is a cross-sectional view illustrating a pixel area of a first semiconductor chip of the image sensor of FIG. 2A;

FIGS. 4A and 4B are cross-sectional views illustrating an optical black region of an image sensor in a comparative example and an optical black region of the image sensor of FIG. 1;

FIG. 5 shows a plan view illustrating the structure of a meta-optical element (MOE) layer in an optical black region of the image sensor of FIG. 1 and a simulation picture of the power distribution of light that has passed through the MOE layer;

FIG. 6 shows a cross-sectional view of the structure of an optical black region of the image sensor of FIG. 1 and a simulation graph illustrating the power of light that has passed through a metal layer;

FIGS. 7A to 7G are cross-sectional views each illustrating an active pixel region and an optical black region in each of image sensors according to some example embodiments; and

FIGS. 8A to 8E are cross-sectional views each illustrating an active pixel region and an optical black region in each of image sensors according to some example embodiments.

### DETAILED DESCRIPTION

Hereinafter, example embodiments will be described in detail with reference to the accompanying drawings. In the drawings, like reference characters denote like elements, and redundant descriptions thereof will be omitted.

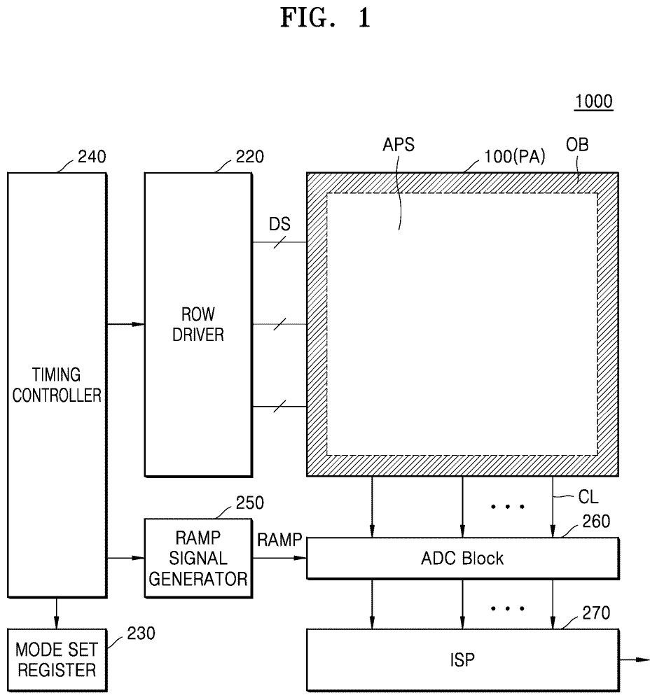

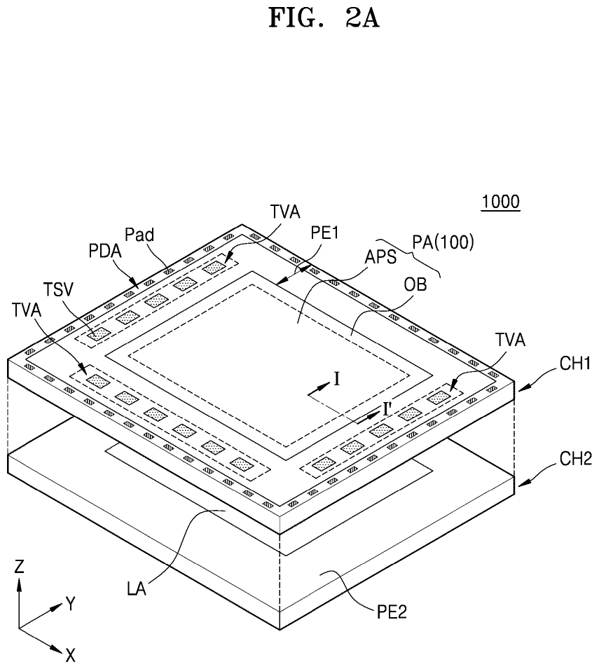

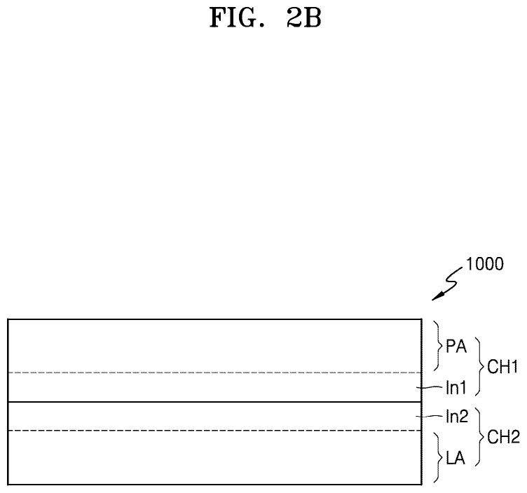

FIG. 1 is a block diagram of an image sensor according to some example embodiments. FIGS. 2A and 2B are respectively a perspective view and a cross-sectional view of the image sensor 1000 of FIG. 1. FIG. 2A is an exploded perspective view separately showing a first semiconductor chip and a second semiconductor chip.

Referring to FIG. 1, an image sensor 1000 of some example embodiments may include a pixel area 100 (or a pixel area PA), a row driver 220, a mode set register 230, a timing controller 240, a ramp signal generator 250, an analog-to-digital converter (ADC) block 260, and an image signal processor (ISP) 270.

The pixel area 100 may include an active pixel region APS and an optical black region OB. As shown in FIG. 1, the active pixel region APS may be in a central portion of the pixel area 100, and the optical black region OB may be in an outer portion of the pixel area 100 and may surround the active pixel region APS. In some example embodiments, an area of the active pixel region APS may be defined by an area of the optical black region OB. In some example embodiments, the active pixel region APS may be referred to as an active pixel sensor region. The active pixel region APS and the optical black region OB may each include a plurality of pixels arranged in a two-dimensional (2D) array structure. Each of the pixels may convert an optical signal into an electrical signal. Pixels in each row may each output an electrical signal to a column line CL in response to a plurality of driving signals DS, such as a pixel select signal, a reset signal, and a charge transfer signal, from the row driver 220.

The row driver 220 may select and drive pixels in the pixel area 100 in units of rows. The row driver 220 may decode a row control signal (e.g., an address signal), which is received from the timing controller 240, and generate and transmit the driving signals DS corresponding to the decoded row line to the pixel area 100.

The mode set register 230 may include a register, in which an application processor (AP) connected to the image sensor 1000 sets an operation mode of the image sensor 1000 through an interface. The AP may change the operating conditions of the image sensor 1000 through the mode set register 230 for each frame.

The timing controller 240 may generally control operations of circuit blocks (e.g., 220, 240, and/or 250) of the image sensor 1000 according to mode set information set in the mode set register 230.

The ramp signal generator 250 may generate a ramp signal RAMP, which increases or decreases with a certain slope (or alternatively, a desired or determined slope), and may provide the ramp signal RAMP to the ADC block 260.

The ADC block 260 may convert an analog electrical signal output from the column line CL of the pixel area 100 into a digital image signal by using correlated double sampling (CDS). The CDS may double sample a noise level and a signal level of a pixel signal transmitted to a column line and may convert a difference level corresponding to the difference between the noise level and the signal level into a digital image signal.

The ISP 270 may process the received image signal and output a final image signal. Signal processing by the ISP 270 may include noise reduction, gain tuning, waveform shaping, interpolation, white balance, gamma processing, edge enhancement, binning, or the like.

In the drawings, a pixel area may be denoted by reference characters PA or reference numeral 100. Here, “PA” may be a concept of a spatial area of the pixel area, and “100” may be a concept including components in the pixel area.

Referring to FIGS. 2A and 2B, the image sensor 1000 may include two semiconductor chips, e.g., a first semiconductor chip CH1 and a second semiconductor chip CH2. The first semiconductor chip CH1 and the second semiconductor chip CH2 may vertically overlap each other and may be stacked on each other. The pixel area 100 of the image sensor 1000 of FIG. 1 may be arranged in the first semiconductor chip CH1. All other circuit blocks (e.g., 220 to 270) excluding the pixel area 100 of the image sensor 1000 of FIG. 1 may be arranged in the second semiconductor chip CH2.

In some example embodiments, an image sensor may have a stack structure of three semiconductor chips. In the stack structure of three semiconductor chips, a part of the pixel area 100 may be arranged in a first semiconductor chip at the top. For example, a photoelectric conversion element or photodiode, a transfer transistor, and a floating diffusion region, which form a pixel or photoelectric conversion element region, may be arranged in the first semiconductor chip. Another part of the pixel area 100 may be arranged in a second semiconductor chip below the first semiconductor chip. For example, pixel transistors, e.g., a reset transistor, a source follower transistor, and a select transistor, excluding the transfer transistor may be arranged in the second semiconductor chip. The transfer transistor and the floating diffusion region of the first semiconductor chip may be connected to the pixel transistors of the second semiconductor chip through a through silicon via (TSV), an inter-chip connection terminal, or the like. The circuit blocks (e.g., 220 to 270) excluding the pixel area 100 may be arranged in a third semiconductor chip below the second semiconductor chip. The third semiconductor chip may be connected to the second semiconductor chip through a TSV, an inter-chip connection terminal, or the like.

In some example embodiments, an image sensor may have a single-chip structure. When the image sensor has a single-chip structure, the pixel area 100 of the image sensor 1000 of FIG. 1 may be arranged in a central region of the image sensor, and all other circuit blocks (e.g., 220 to 270) excluding the pixel area 100 of the image sensor 1000 of FIG. 1 may be arranged in a peripheral region of the image sensor.

In the image sensor 1000, the pixel area 100 may be arranged in a central portion of the first semiconductor chip CH1. A first peripheral area PE1 may be arranged outside the pixel area 100 in the first semiconductor chip CH1. The first peripheral area PE1 may surround the pixel area 100, that is, the first peripheral area PE1 may define the pixel area 100. For example, the first peripheral area PE1 may include a through via region TVA and a pad region PDA. The through via region TVA may be adjacent to the optical black region OB. A through electrode TSV may be arranged in the through via region TVA. The pad region PDA may be in an outermost part of the first peripheral area PE1. In some example embodiments, the pad region PDA may define an edge or border of the first peripheral area PE1 and/or the image sensor 1000. A pad Pad may be arranged in the pad region PDA.

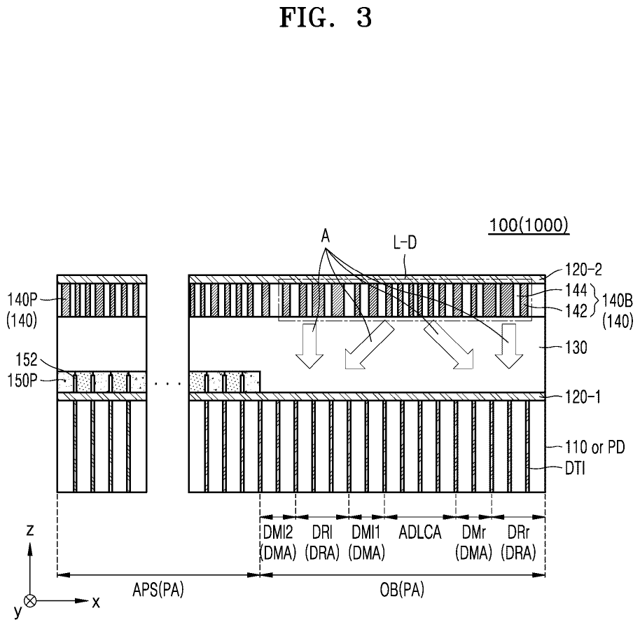

Although now shown, a contact region may be between the through via region TVA and the optical black region OB. Backside contacts may be arranged in the contact region. A backside contact may be connected to a conductive layer of a pixel isolation structure DTI (see FIG. 3) of the pixel area 100 and may apply a certain voltage (or alternatively, a desired or determined slope), e.g., a ground voltage or a negative voltage, to the pixel isolation structure DTI. Because the ground or negative voltage is applied to the pixel isolation structure DTI through the backside contact, a dark current characteristic may be improved.

The second semiconductor chip CH2 may include a logic area LA including logic devices and a second peripheral area PE2 including peripheral circuits. The logic area LA may be arranged in a central portion of the second semiconductor chip CH2, and the second peripheral area PE2 may surround the logic area LA. All circuit blocks (e.g., 220 to 270) excluding the pixel area 100 of the image sensor 1000 of FIG. 1 may be arranged in the logic area LA.

As see in FIG. 2B, a first wiring layer In1 may be in a lower portion of the first semiconductor chip CH1, and the pixel area PA may be disposed on the first wiring layer In1 in the first semiconductor chip CH1. A second wiring layer In2 may be in an upper portion of the second semiconductor chip CH2, and the logic area LA may be below the second wiring layer In2 in the second semiconductor chip CH2. In FIG. 2B, the pixel area PA of the first semiconductor chip CH1 may include a first substrate in which pixels are formed. The logic area LA of the second semiconductor chip CH2 may include a second substrate in which transistors for logic devices are formed.

The first semiconductor chip CH1 may be stacked on the second semiconductor chip CH2 such that the first wiring layer In1 faces the second wiring layer In2. The first semiconductor chip CH1 and the second semiconductor chip CH2 may exchange signals with each other through the through electrode TSV or an inter-chip connection terminal. For example, in the image sensor 1000 of some example embodiments, the first semiconductor chip CH1 and the second semiconductor chip CH2 may exchange signals with each other through the through electrode TSV, which passes through a portion of the second wiring layer In2 and the first semiconductor chip CH1.

In the image sensor 1000 of some example embodiments, the pixel area 100 may include a meta-optical element (MOE) layer 140 (see FIG. 3). The MOE layer 140 may include a first MOE layer 140P in the active pixel region APS and a second MOE layer 140B in the optical black region OB. The second MOE layer 140B may route light, which is incident to an auto dark level compensation (ADLC) region ADLCA (see FIG. 3) in the optical black region OB, to a dummy region DMA (see FIG. 3) and a drain region DRA (see FIG. 3), thereby increasing ADLC performance. The structure of the pixel area 100 including the MOE layer 140 is described in detail with reference to FIG. 3 below.

FIG. 3 is a cross-sectional view illustrating a pixel area of a first semiconductor chip of the image sensor 1000 of FIG. 2A. FIG. 3 is a cross-section view taken along line I-I′ in FIG. 2A. The first wiring layer In1 is omitted from FIG. 3. FIGS. 1 to 2B are also referred to, and redundant descriptions given above with reference to FIGS. 1 to 2B are brief or omitted.

Referring to FIG. 3, in the image sensor 1000 of some example embodiments, the first semiconductor chip CH1 may include a first substrate and the first wiring layer In1 (in FIG. 2B). The first substrate may include silicon (Si). For example, the first substrate may include a silicon monocrystalline substrate, a silicon epitaxial substrate, or a silicon-on-insulator (SOI) substrate. However, the material of the first substrate is not limited to Si. For example, the first substrate may include a single-element semiconductor, such as germanium (Ge), or a compound semiconductor, such as silicon carbide (SiC), gallium arsenide (GaAs), indium arsenide (InAs), or indium phosphide (InP). For example, the first substrate may be doped with impurities of a first conductivity type. Here, the first conductivity type may include a P-type. However, the first conductivity type is not limited to the P-type. The bottom surface of the first substrate may correspond to a front side, e.g., an active side, and the top surface of the first substrate may correspond to a back side, e.g., an inactive side.

In a plan view, the first semiconductor chip CH1 may include the pixel area PA and the first peripheral area PE1. As described with reference to FIG. 1, the pixel area PA may include the active pixel region APS and the optical black region OB. The optical black region OB may surround the active pixel region APS. A plurality of pixels 110 (or photoelectric conversion element (PD) regions 110) may be arranged in the first substrate in the active pixel region APS and the optical black region OB. The first peripheral area PE1 may surround the pixel area PA, e.g., the optical black region OB.

The pixel isolation structure DTI may be arranged in the first substrate in the active pixel region APS and the optical black region OB to isolate the pixels 110 from each other. The pixel isolation structure DTI may also be arranged in at least a portion of the first peripheral area PE1. In a plan view, the pixel isolation structure DTI may have a mesh shape. The pixel isolation structure DTI may pass through the first substrate in the z-direction. Because the pixel isolation structure DTI passes through the first substrate, crosstalk may be reduced or prevented from occurring due to obliquely incident light. The first substrate may be arranged only in the first peripheral area PE1. Most of the first substrate may be removed from the pixel area PA, and the pixels 110 may be arranged in a portion from which the first substrate has been removed.

The pixel isolation structure DTI may have a front deep trench isolation (FDTI) structure in which the pixel isolation structure DTI extends from the front side of the first substrate to the back side of the first substrate. In some example embodiments, the pixel isolation structure DTI may have a back DTI (BDTI) structure in which the pixel isolation structure DTI extends from the back side of the first substrate to the front side of the first substrate. The FDTI structure and the BDTI structure may be identified according to whether the width of the structure at the front side is greater than the width thereof at the back side. In other words, the pixel isolation structure DTI may be formed by forming a trench in the first substrate and filling the trench with an insulating material and a conductive material. Accordingly, in the case of the FDTI structure in which a trench is dug in the front side of the first substrate, a width of the trench at the front side may be greater than that at the back side. Contrarily, in the case of the BDTI structure in which a trench is dug in the back side of the first substrate, a width of the trench at the back side may be greater than that at the front side.

Although it is illustrated in FIG. 3 that the pixel isolation structure DTI has a single layer, the pixel isolation structure DTI may have a multi-layer structure. For example, the pixel isolation structure DTI may include a conductive pattern at the center thereof and a side insulating layer surrounding the conductive pattern. The pixel isolation structure DTI may further include an insulating pattern below the conductive pattern. The side insulating layer and the insulating pattern may insulate the conductive pattern from the first substrate.

A photoelectric conversion element (or photodiode) PD may be doped with impurities of a second conductivity type opposite to the first conductivity type. For example, the second conductivity type may include an N-type. A region doped with N-type impurities may form a PN junction with the first substrate, which is around the region and doped with P-type impurities, thereby forming the photoelectric conversion element PD.

A shallow trench isolation pattern (STI) may be arranged adjacent to the front side of the first substrate. The pixel isolation structure DTI may pass through the STI. In some example embodiments, the pixel isolation structure DTI may be in contact with the STI. An active region may be defined by the STI in a pixel 110. A floating diffusion region and pixel transistors of the pixel 110 may be arranged in the active region. Here, the pixel transistors may include a transfer transistor, a reset transistor, a source follower transistor, and a select transistor. The photoelectric conversion element PD may be arranged in the pixel 110 and may occupy most of the pixel 110, for example, the photoelectric conversion element PD may occupy over half (50%) of the pixel 110. Accordingly, hereinafter, the pixel 110 and the photoelectric conversion element PD may be used with substantially the same meaning.

The image sensor 1000 of some example embodiments may have a back side illumination (BSI) structure. The BSI structure may refer to a structure in which light is incident to the back side of the first substrate. Accordingly, in the first semiconductor chip CH1 of the image sensor 1000 of some example embodiments, a structure through which light is incident may be arranged on an upper portion of the first substrate in which the pixel 110 is formed (the upper portion corresponding to the back side), and the first wiring layer In1 may be arranged at the front side corresponding to a lower portion of the first substrate. The first semiconductor chip CH1 of the image sensor 1000 of some example embodiments may include the MOE layer 140, and the MOE layer 140 may be the structure through which light is incident. Light may be incident to the photoelectric conversion element PD of the pixel 110 through the MOE layer 140. For example, light must pass through the MOE layer 140 to be incident to the photoelectric conversion element PD of the pixel 110. Electron-hole pairs may be generated in the photoelectric conversion element PD by light incident to the photoelectric conversion element PD, and electrons may be accumulated in the photoelectric conversion element PD. Thereafter, when a transfer transistor is turned on, electrons accumulated in the photoelectric conversion element PD may move to a floating diffusion region. The MOE layer 140 and a structure therebelow are described in detail below. There is a front side illumination (FSI) structure that is opposite to the BSI structure. The FSI structure may refer to a structure in which the first wiring layer In1 and a structure through which light is incident are arranged together on the front side of the first substrate.

The first semiconductor chip CH1 may include the first wiring layer In1 on the front side in a lower portion of the first substrate. The first wiring layer In1 may include an interlayer insulating film and wiring lines. The interlayer insulating film may include at least one selected from the group consisting of silicon oxide, silicon nitride, silicon oxynitride, and a porous low-k material and may have a multi-layer structure. The wiring lines may be arranged inside the interlayer insulating film and may have a multi-layer structure in correspondence to the multi-layer structure of the interlayer insulating film. Wiring lines respectively in different layers may be connected to each other by a via contact. The wiring lines may also be connected to the floating diffusion region and a gate of the transfer transistor through a via contact.

A first anti-reflection layer (ARL) 120-1 may be on the back side of the first substrate. The first ARL 120-1 may be arranged throughout the pixel area PA and the first peripheral area PE1. The first ARL 120-1 may have a single-layer or multi-layer structure. The first ARL 120-1 may suppress reflection of incident light and may increase the amount of light incident to the photoelectric conversion element PD.

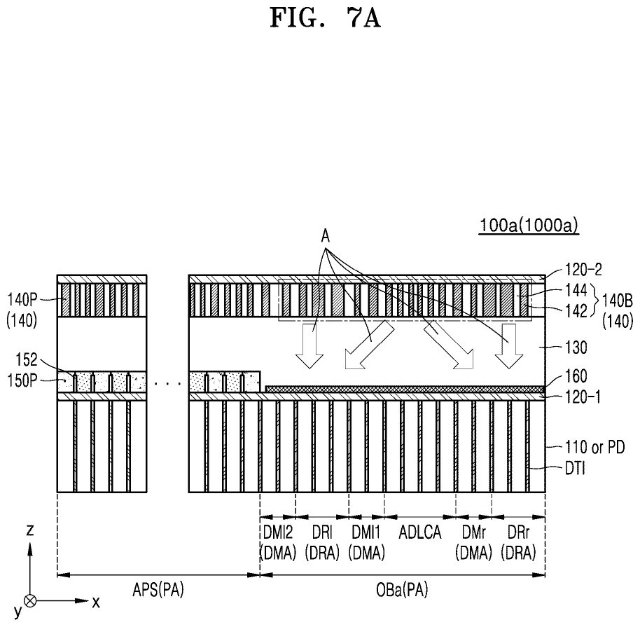

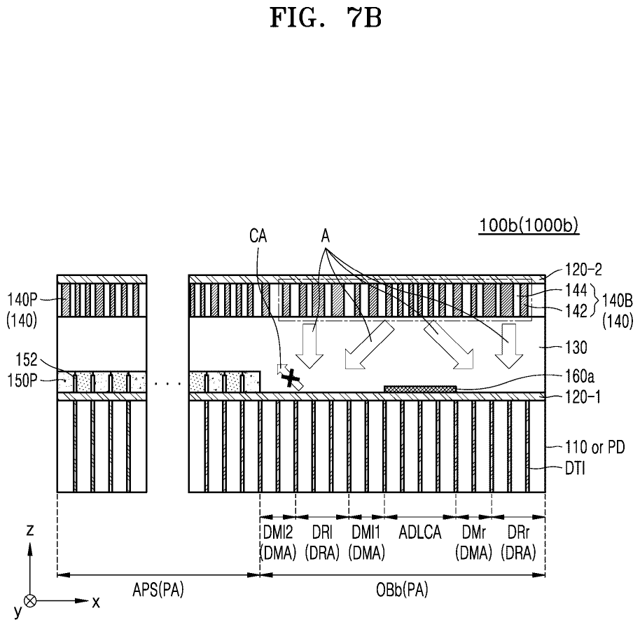

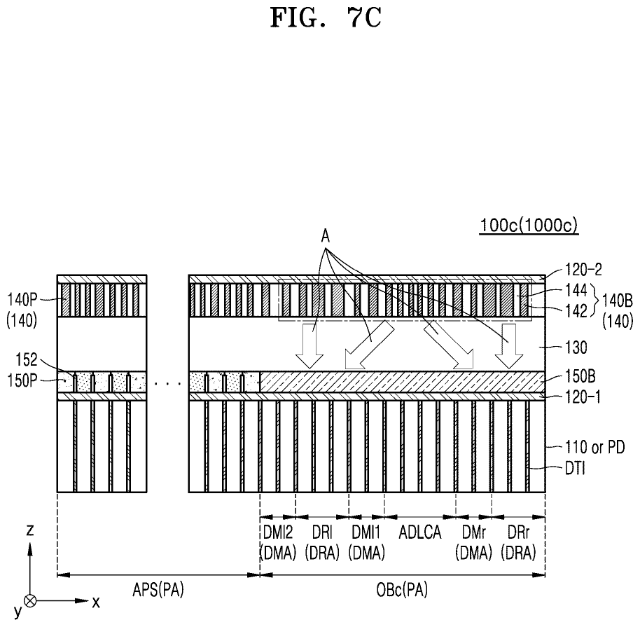

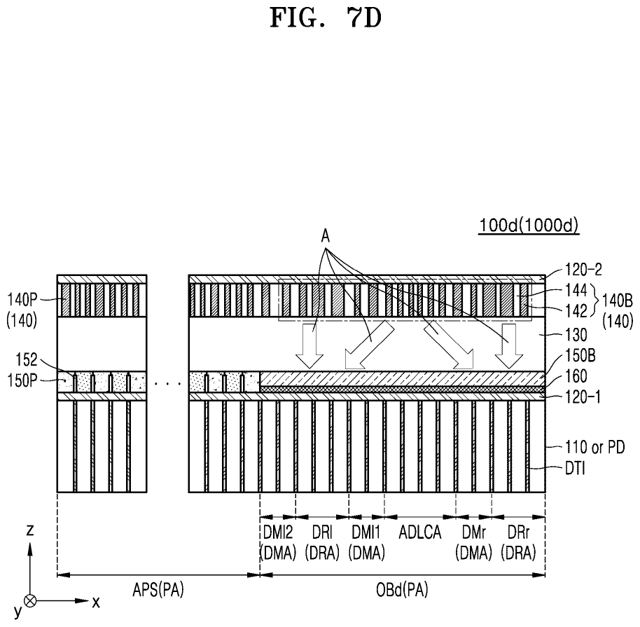

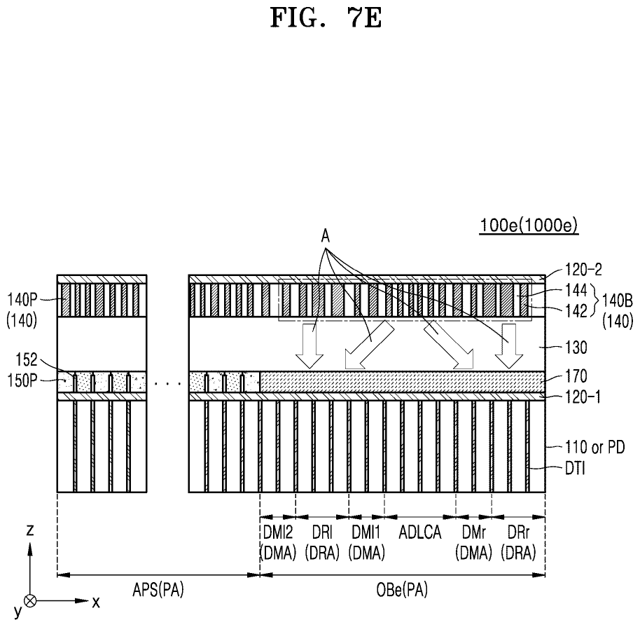

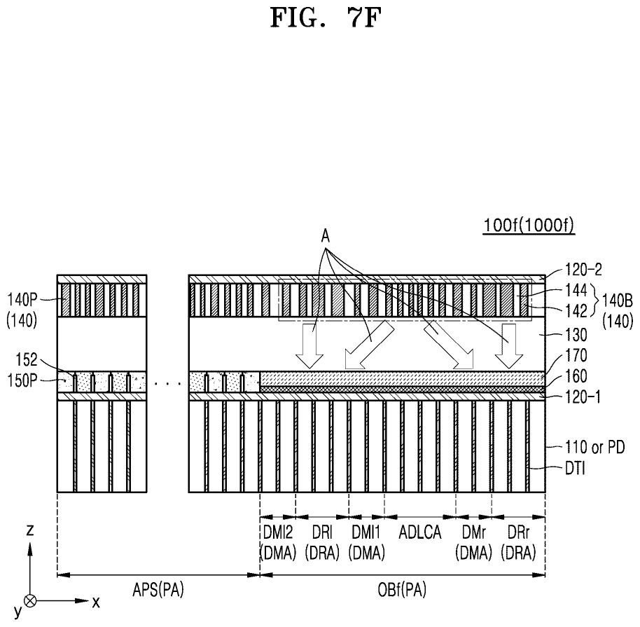

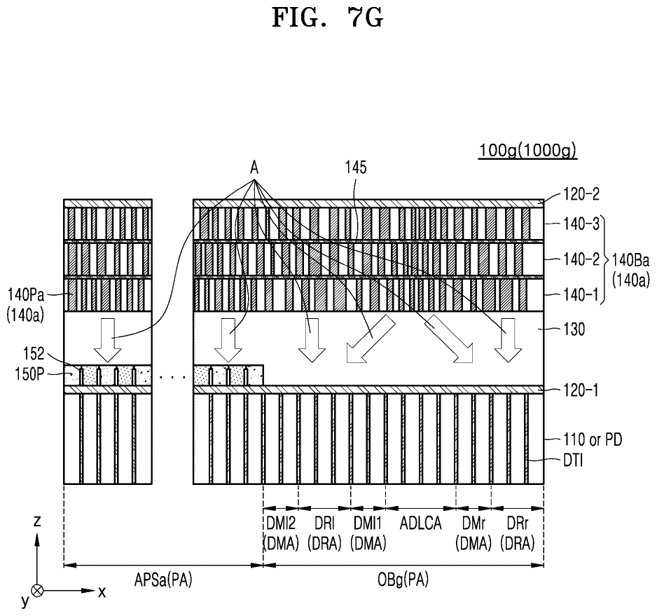

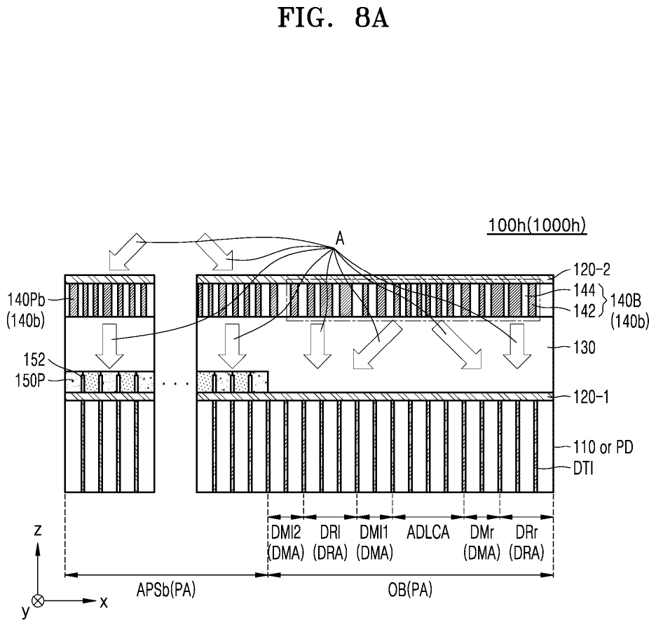

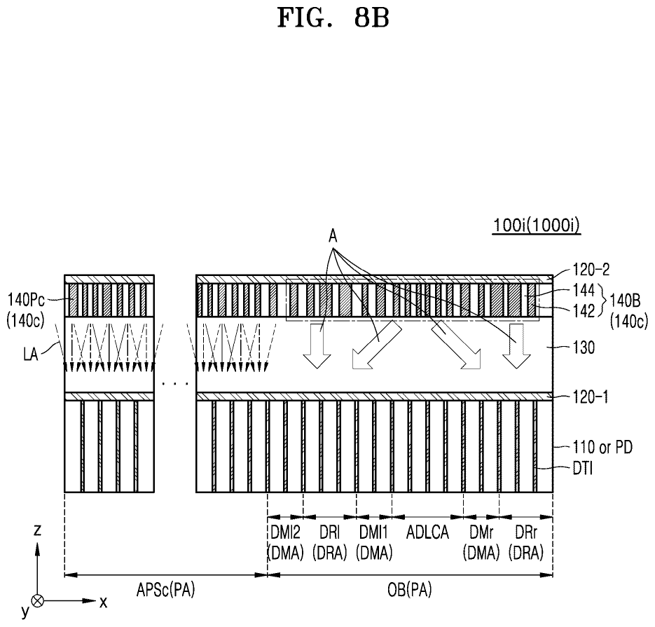

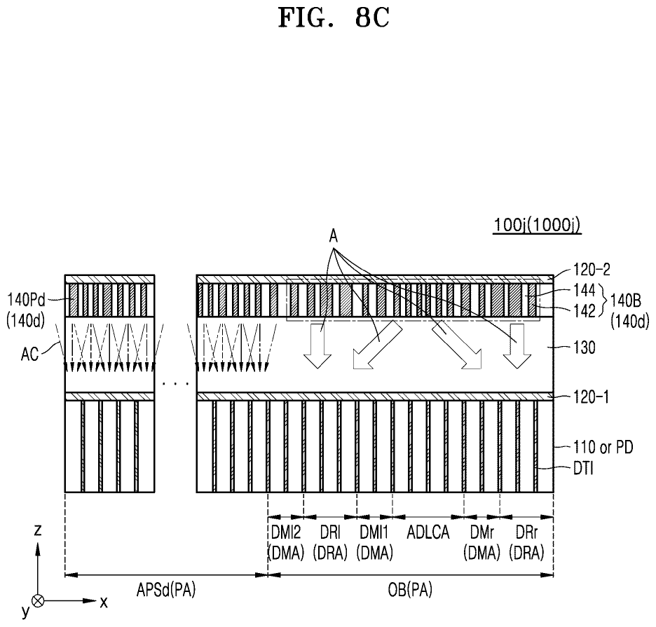

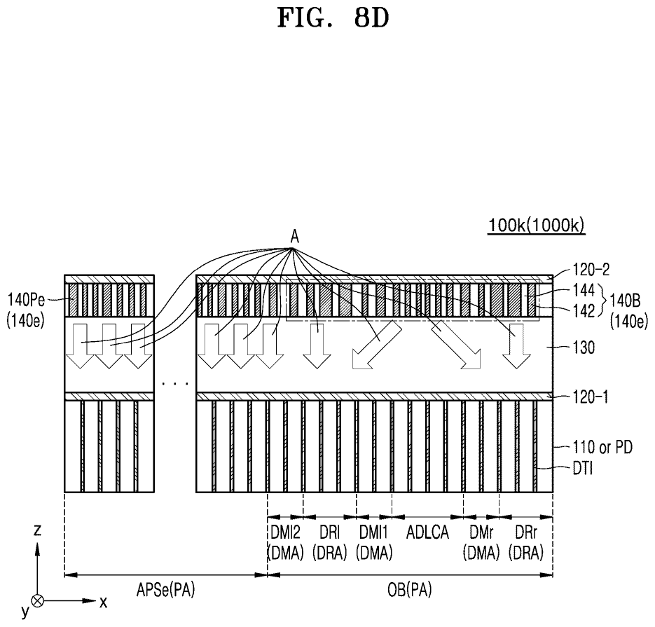

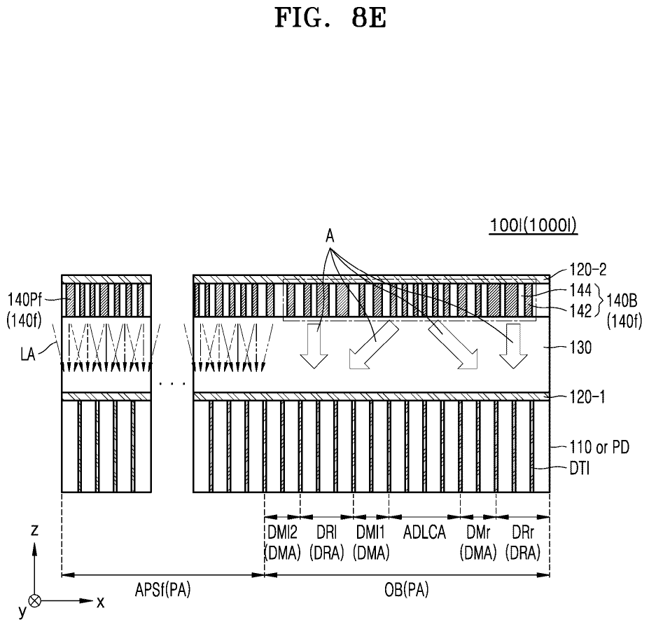

A structure above the first ARL 120-1 in the active pixel region APS may be different from the structure above the first ARL 120-1 in the optical black region OB. The structure above the first ARL 120-1 may vary in the active pixel region APS. The structure above the first ARL 120-1 may also vary in the optical black region OB. Hereinafter, basic components arranged in the active pixel region APS and the optical black region OB are described based on FIG. 3. Various structures above the first ARL 120-1 in the optical black region OB are described in detail with reference to FIGS. 7A to 7G. Various structures above the first ARL 120-1 in the active pixel region APS are described in detail with reference to FIGS. 8A to 8E.

A first color filter layer 150P may be arranged on the first ARL 120-1 in the active pixel region APS. The first color filter layer 150P may include multiple color filters. For example, the color filters of the first color filter layer 150P may be separated from each other by a grid pattern 152. For example, each of the color filters of the first color filter layer 150P may have one color among blue, green, and red. In some example embodiments, the color filters of the first color filter layer 150P may have a color combination of cyan, magenta, and yellow. In the image sensor 1000 of some example embodiments, the color filters of the first color filter layer 150P may be arranged in a bayer pattern. In some example embodiments, the color filters of the first color filter layer 150P may be arranged in a 2×2 tetra pattern, a 3×3 nona pattern, or a 4×4 hexadeca pattern. However, example embodiments are not limited thereto.

In some example embodiments, the color filters of the first color filter layer 150P may include, for example, an organic color filter. Because the organic color filter has no or nearly no light loss, the organic color filter may provide a significant amount of light to a pixel even when the size of the pixel decreases. Therefore, organic color filters may enable manufacture of improved ultrahigh-resolution, ultra-small, high-sensitivity image sensors having hundreds of millions of pixels. The ultrahigh-resolution, ultra-small, high-sensitivity image sensor may be used in various high-performance optical devices or high-performance electronic devices. Examples of high-performance electronic devices may include smartphones, portable phones, mobile phones, personal digital assistants (PDAs), laptops, personal computers (PCs), various portable devices, home appliances, security cameras, medical cameras, automobiles, Internet of things (IoT) devices, and other mobile or non-mobile computing devices. However, the high-performance electronic devices are not limited thereto.

The grid pattern 152 may include metal or an organic or inorganic material having a low refractive index. When the grid pattern 152 includes an organic or inorganic material, the grid pattern 152 may have a lower refractive index than the color filters of the first color filter layer 150P. For example, the grid pattern 152 may have a refractive index of about or exactly 1.3 or less (e.g., about or exactly 0). However, the refractive index of the grid pattern 152 is not limited to the numerical range mentioned above. The grid pattern 152 may reduce or prevent crosstalk between adjacent pixels 110.

In detail, the grid pattern 152 may have a mesh shape in a plan view and may vertically overlap the pixel isolation structure DTI. The grid pattern 152 may have uniform width and thickness and include an insulating material having a low refractive index. For example, the grid pattern 152 may include tetraethyl orthosilicate (TEOS), plasma-enhanced TEOS (PETEOS), and/or a porous low-k material. Here, PETEOS may refer to TEOS formed through a plasma process.

The grid pattern 152 may have a single-insulating layer structure. In some example embodiments, the grid pattern 152 may have a multi-insulating layer structure. Although not shown, a protective film reducing or preventing moisture absorption may cover the grid pattern 152 to a uniform thickness. In some example embodiments, the grid pattern 152 may not include a metal layer such as a Ti/TiN layer. When the grid pattern 152 does not include a metal layer, quantum efficiency (QE) loss may be reduced or prevented from occurring due to light absorption of the metal layer. Accordingly, QE of an image sensor may be increased.

In the image sensor 1000 of some example embodiments, a color filter layer may not be arranged on the first ARL 120-1 in the optical black region OB. Because the color filter layer is not arranged, a grid pattern may not be arranged either. As shown in FIG. 3, the optical black region OB may include an ADLC region ADLCA, a dummy region DMA, and a drain region DRA. The dummy region DMA and the drain region DRA may be sequentially arranged at opposite sides of the ADLC region ADLCA in the x-direction. For example, the dummy region DMA may include a left first dummy region DMI1 and a left second dummy region DMI2 on the left of the ADLC region ADLCA and a right dummy region DMr on the right of the ADLC region ADLCA in the x-direction. The drain region DRA may also include a left drain region DRI on the left of the ADLC region ADLCA and a right drain region DRr on the right of the ADLC region ADLCA in the x-direction. In some example embodiments, more dummy regions may be arranged on the right side in the x-direction.

A photoelectric conversion element PD may be arranged in the optical black region OB. The structure of the photoelectric conversion element PD in the optical black region OB may be the same or substantially the same as the structure of a photoelectric conversion element PD in the active pixel region APS. However, the photoelectric conversion element PD in the optical black region OB may not perform the same operation (e.g., an operation of generating an electrical signal according to the amount of incident light) as the photoelectric conversion element PD in the active pixel region APS.

The photoelectric conversion element PD in the ADLC region ADLCA of the optical black region OB may function as a reference pixel. In other words, the photoelectric conversion element PD in the ADLC region ADLCA may generate a dark level reference signal, and the ISP 270 in FIG. 1 may compensate for the dark level of output values of pixels in the active pixel region APS by using the dark level reference signal. The drain region DRA of the optical black region OB may drain a signal generated in the optical black region OB, and the dummy region DMA of the optical black region OB may block external signals from entering the ADLC region ADLCA.

A spacer layer 130 may be arranged on the first color filter layer 150P in the active pixel region APS and the first ARL 120-1 in the optical black region OB. The spacer layer 130 may be between the pixel 110 and the MOE layer 140 and may maintain the distance between the pixel 110 and the MOE layer 140 constant. The spacer layer 130 may include a transparent material, such as SiO₂ or siloxane-based spin-on-glass (SOG). The spacer layer 130 may include a dielectric material having a lower refractive index and a lower absorption rate than a nano-post 142 of the MOE layer 140. The thickness of the spacer layer 130 may be determined based on a horizontal distance that light deflected by the MOE layer 140 travels on the top surface of the pixel 110. For example, the spacer layer 130 may have a thickness such that light incident to the center of the ADLC region ADLCA in the x-direction may be deflected by the MOE layer 140 and incident to a region, e.g., the dummy region DMA or the drain region DRA, outside the ADLC region ADLCA. Because the first color filter layer 150P is arranged in the active pixel region APS, the spacer layer 130 may be thinner in the active pixel region APS than in the optical black region OB.

The MOE layer 140 may be arranged on the spacer layer 130 in the active pixel region APS and the optical black region OB. The MOE layer 140 may be supported by the spacer layer 130. The MOE layer 140 may include the nano-post 142 and a dielectric layer 144. The nano-post 142 may include a high-refractive index material that changes the phase of incident light. For example, the nano-post 142 may include silicon (Si), silicon nitride (SiNₓ), gallium nitride (GaN), titanium oxide (TiO₂), tantalum oxide (TaO₂), zirconium oxide (ZrO₂), or hafnium oxide (HfO₂). However, the material of the nano-post 142 is not limited to those mentioned above. The dielectric layer 144 may be arranged between nano-posts 142 and may include a low-refractive index material having a lower refractive index than the nano-post 142. For example, the dielectric layer 144 may include air or SiO₂. The material of the dielectric layer 144 is not limited to thereto. For example, the dielectric layer 144 may include siloxane-based SOG that is included in the spacer layer 130.

The nano-post 142 may have a cylindrical shape extending in the z-direction. A plurality of nano-posts 142 may have different diameters from each other. For example, the nano-posts 142 may have various diameters of about or exactly 40 nm to about or exactly 400 nm. The nano-posts 142 may be spaced apart from one another by different horizontal distances. That is, a distance between the nano-posts 142 may be irregular or different, and may have a repeating pattern or be random. Here, a horizontal distance may refer to a distance on a plane perpendicular to the z-direction. For example, the horizontal distance may include a distance in the x-direction, the y-direction, or a diagonal direction on the plane.

The MOE layer 140 may be divided into the first MOE layer 140P in the active pixel region APS and the second MOE layer 140B in the optical black region OB. The first MOE layer 140P and the second MOE layer 140B may have different pattern structures from each other. Here, the pattern structure may refer to the size, shape, spacing, and/or arrangement of the nano-posts 142. For example, the first MOE layer 140P may have a pattern structure corresponding to a purpose required for the active pixel region APS. For example, the second MOE layer 140B may have a pattern structure that deflects light so that the light is not incident to the ADLC region ADLCA.

To be more specific, the first MOE layer 140P may serve as a microlens in the active pixel region APS. In this case, the first MOE layer 140P may not only focus incident light regardless of wavelengths but also focus incident light by wavelength. Light focusing by wavelength is described in detail with reference to FIGS. 8B to 8D. The first MOE layer 140P may focus light on the color filters of the first color filter layer 150P. Due to the light focusing by the first MOE layer 140P, QE higher than 100% of an existing microlens may be achieved.

The MOE layer 140 may include nano-posts 142 of which the size, shape, spacing, and/or arrangement is adjusted to allow light to be focused on the color filters. The thickness of the first MOE layer 140P in the vertical direction, i.e., the z-direction, may be the same or substantially the same as the height of the nano-posts 142 in the z-direction. For example, the thickness of the first MOE layer 140P may be about or exactly 500 nm to about or exactly 1500 nm. However, the thickness of the first MOE layer 140P is not limited to the numerical range mentioned above. Various roles of the first MOE layer 140P in the active pixel region APS other than the role as the microlens are described in detail with reference to FIGS. 8A to 8E below.

As shown by the empty arrows A in FIG. 3, the second MOE layer 140B may deflect light such that the light is incident to the outside of the ADLC region ADLCA. For example, the second MOE layer 140B may correspond to a type of light-deflector L-D. The second MOE layer 140B may include nano-posts 142 of which the size, shape, spacing, and/or arrangement is adjusted to have a deflection angle set with respect to incident light. The thickness of the second MOE layer 140B in the z-direction may be the same or substantially the same as the height of the nano-posts 142 in the z-direction. The thickness of the second MOE layer 140B may be the same or substantially the same as the thickness of the first MOE layer 140P. In some example embodiments, the second MOE layer 140B may not only deflect incident light regardless of wavelengths but also deflect incident light by wavelength.

Although not shown, an etch stop layer may be selectively arranged between the spacer layer 130 and the MOE layer 140. The etch stop layer may protect the spacer layer 130 from being damaged in a process of forming the nano-posts 142. The etch stop layer may include a transparent dielectric material having a high etch selectivity with respect to the spacer layer 130. For example, the etch stop layer may include at least one selected from the group consisting of aluminum oxide (Al₂O₃), hafnium oxide (HfO₂), and silicon nitride (SiNₓ). The etch stop layer may have a thickness capable of protecting a lower layer, e.g., the spacer layer 130, without impairing the optical characteristics of the MOE layer 140. For example, the etch stop layer may have a thickness of about or exactly 3 nm to about or exactly 50 nm. However, the thickness of the etch stop layer is not limited to the numerical range mentioned above. To minimize or reduce the increase in reflectance of the etch stop layer, the etch stop layer may not cover the entire surface of the spacer layer 130. In other words, the etch stop layer may cover only a portion of the surface of the spacer layer 130.

A second ARL 120-2 may be arranged on the MOE layer 140 in the active pixel region APS and the optical black region OB. The second ARL 120-2 may have a single-layer or multi-layer structure. When the second ARL 120-2 has a multi-layer structure, the materials of multiple layers may have different refractive indices.

The second ARL 120-2 may include a pattern that reduces reflection of incident light. For example, the second ARL 120-2 may include a plurality of nano-scale patterns. The patterns may be arranged in a quasi-periodic manner. In some example embodiments, the patterns of the second ARL 120-2 may have random sizes and/or spacing.

The patterns of the second ARL 120-2 may be arranged considering overlap with the nano-posts 142. For example, the patterns of the second ARL 120-2 may have a pitch that is different from the pitch of the nano-posts 142. The patterns of the second ARL 120-2 may be non-periodically arranged. Accordingly, the patterns of the second ARL 120-2 may be reduced or prevented from periodically overlapping the nano-posts 142 so that the occurrence of image artifacts may be suppressed.

The patterns of the second ARL 120-2 may have random shapes. For example, the patterns of the second ARL 120-2 may have a cylindrical shape, a prismatic shape, a cone shape, a polyhedral shape, or the like. In some example embodiments, the patterns of the second ARL 120-2 may have a curved surface. For example, a side of the patterns of the second ARL 120-2 may have a concave or convex curved surface. In some example embodiments, the height and width of the patterns of the second ARL 120-2 may be determined based on the wavelength of incident light.

The image sensor 1000 of some example embodiments may include the MOE layer 140 in the pixel area 100. Accordingly, the image sensor 1000 of some example embodiments may be used in all products to which meta-optics is applied. In the image sensor 1000 of some example embodiments, the MOE layer 140 may include the first MOE layer 140P in the active pixel region APS and the second MOE layer 140B in the optical black region OB. The first MOE layer 140P may serve as a microlens, and the second MOE layer 140B may serve as the light-deflector L-D. Accordingly, the image sensor 1000 of some example embodiments may route light, which heads toward the ADLC region ADLCA through the second MOE layer 140B in the optical black region OB, to the dummy region DMA and the drain region DRA, thereby increasing ADLC performance. For example, dark shading and picture quality may be improved based on a signal of the ADLC region ADLCA in which light is minimized or reduced, and thus, the quality of image signals may be increased. In addition, the image sensor 1000 of some example embodiments may suppress light from entering the ADLC region ADLCA by using the second MOE layer 140B so that a metal layer may be formed thin or narrow in the optical black region OB or a structure without a metal layer may be formed in the optical black region OB. Accordingly, the freedom of a metal process may be increased.

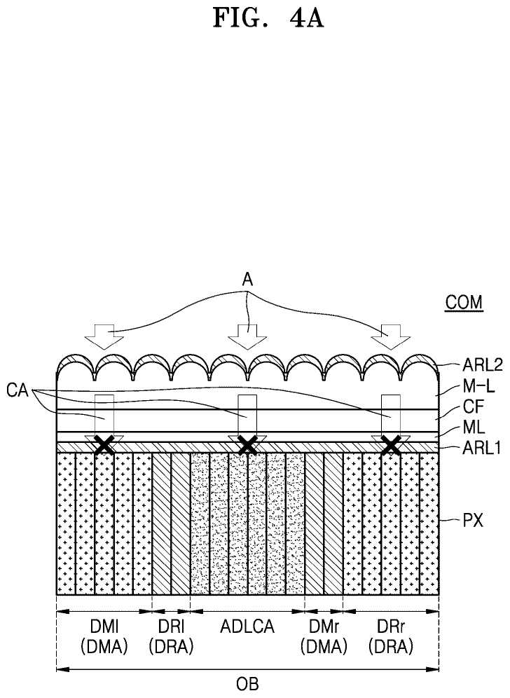

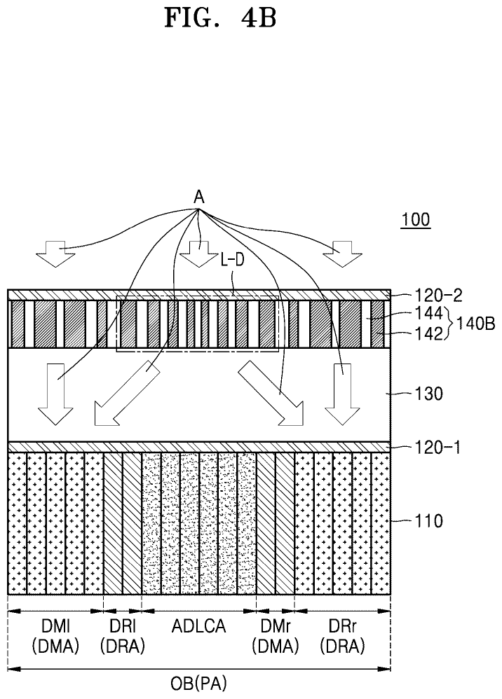

FIGS. 4A and 4B are cross-sectional views illustrating an optical black region of an image sensor in a comparative example and the optical black region OB of the image sensor of FIG. 1. Redundant descriptions given above with reference to FIGS. 1 to 3 are brief or omitted.

Referring to FIGS. 4A and 4B, an image sensor COM in the comparative example may have a structure in which a first anti-reflection layer ARL1, a metal layer ML, a color filter layer CF, a microlens M-L, and a second anti-reflection layer ARL2 are sequentially arranged on a pixel PX in the optical black region OB. In the image sensor COM, the metal layer ML and the color filter layer CF block light, and the metal layer ML may have a thickness of several hundreds of nm or greater (e.g., about or exactly 200 nm to about or exactly 1000 nm) to increase light blocking effect shown by crossed arrows CA. The metal layer ML is arranged throughout the optical black region OB, and a flare phenomenon may occur due to light reflection of the metal layer ML. The flare phenomenon may cause degradation in the quality of image signals.

Contrarily, in the image sensor 1000 of some example embodiments, the optical black region OB may have a structure in which the first ARL 120-1, the spacer layer 130, the second MOE layer 140B, and the second ARL 120-2 are sequentially arranged on the pixel 110. As shown by the empty arrows A, the second MOE layer 140B may serve as the light-deflector L-D, thereby suppressing light from entering the ADLC region ADLCA. Accordingly, a metal layer may be formed thin or narrow in the optical black region OB, or a metal layer may be completely removed from the optical black region OB. Consequently, the freedom of a metal process may be increased, and a flare phenomenon caused by the metal layer may be reduced or eliminated.

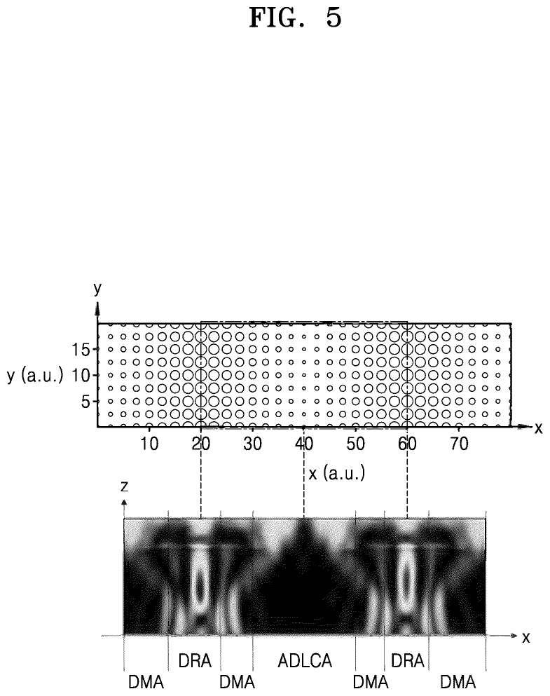

FIG. 5 shows a plan view illustrating the structure of an MOE layer in an optical black region of the image sensor of FIG. 1 and a simulation picture of the power distribution of light that has passed through the MOE layer. In the upper plan view, the x-axis and the y-axis indicate a planar position in arbitrary units in an optical black region. The lower simulation picture shows the power distribution of light in a vertical cross-sectional view corresponding to the upper plan view.

Referring to FIG. 5, in the upper plan view, small circles may correspond to nano-posts 142 of the second MOE layer 140B. The nano-posts 142 may have the smallest diameter in a central portion of the ADLC region ADLCA in the x-direction. The diameter of the nano-posts 142 may increase away from the center of the ADLC region ADLCA in the x-direction. In other words, the diameter of the nano-posts 142 may increase toward the drain region DRA from the ADLC region ADLCA in the x-direction. On the basis of the drain region DRA, the nano-posts 142 may have the largest diameter in a central portion of the drain region DRA in the x-direction, and the diameter of the nano-posts 142 may decrease away from the central portion of the drain region DRA in the x-direction. In some example embodiments, a distance between center points of the nano-posts 142 may be regular (e.g., such that distances between center points is the same, but distances between sidewalls are different due to different diameters) or irregular, and may have a pattern (e.g., larger distances with smaller diameters, based on light reflection/filtering principles, and/or the like) or be irregular.

The lower simulation picture is a black and white picture, to which a color picture is converted and in which blue and red appear as black and green and yellow appear as white. In the simulation picture, most of black may correspond to blue (for example, over half (50%) of the black may correspond to blue), and a small oval black portion surrounded by white in the drain region DRA may correspond to red. Consequently, it may be seen that after passing through the second MOE layer 140B, light has low power in all or most of the optical black region OB excluding the drain region DRA. In particular, because light is routed by the second MOE layer 140B, the power of the light may be very low in a lower portion of the ADLC region ADLCA.

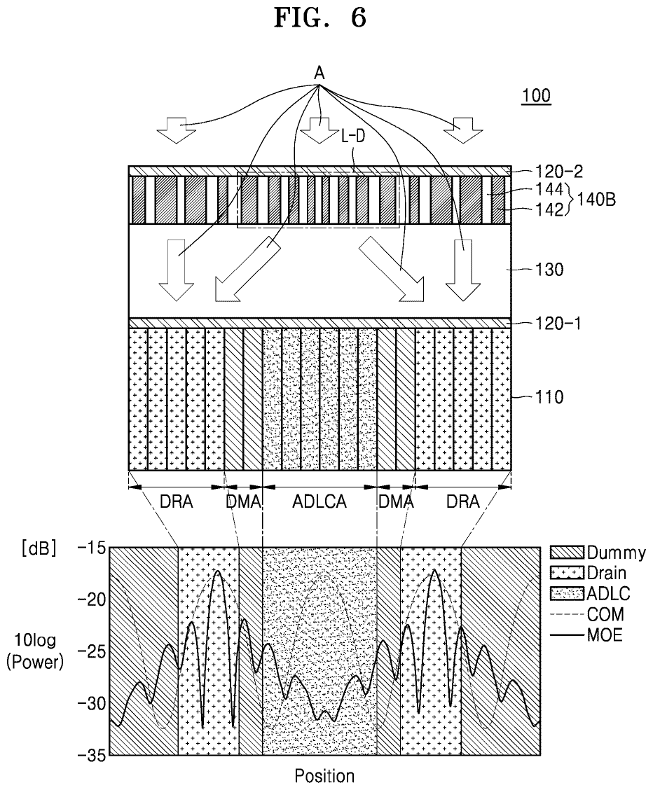

FIG. 6 shows a cross-sectional view of the structure of an optical black region of the image sensor of FIG. 1 and a simulation graph illustrating the power of light that has passed through a metal layer. In the lower graph, the x-axis indicates a position in the x-direction, and the y-axis indicates the power of light in units of dB. The thin dashed line indicates the power of light in an image sensor COM in a comparative example, and the bold solid line indicates the power of light in an image sensor MOE of some example embodiments.

Referring to FIG. 6, as seen in the graph, the image sensor COM in the comparative example may have relatively high power of light in the ADLC region ADLCA. Contrarily, it may be seen that the image sensor MOE of some example embodiments has relatively very low power of light in the ADLC region ADLCA.

The graph in FIG. 6 shows the power of light that has passed through a metal layer in a structure in which the metal layer of tungsten (W) is arranged on a first ARL to a thickness of 1000 Å in each of the image sensor COM of the comparative example and the image sensor MOE of some example embodiments. When there is no metal layer, the graph may show an overall increase by several dB, but the shape of the graph may be similarly maintained.

FIGS. 7A to 7G are cross-sectional views each illustrating an active pixel region and an optical black region in each of image sensors according to some example embodiments. FIGS. 1 to 3 are also referred to, and redundant descriptions given above with reference to FIGS. 1 to 6 are brief or omitted.

Referring to FIG. 7A, an image sensor 1000a of some example embodiments may be different from the image sensor 1000 of FIG. 3 in that a metal layer 160 is further provided in an optical black region Oba. Specifically, the image sensor 1000a may include a pixel area 100a, the row driver 220, the mode set register 230, the timing controller 240, the ramp signal generator 250, the ADC block 260, and the ISP 270. The row driver 220, the mode set register 230, the timing controller 240, the ramp signal generator 250, the ADC block 260, and the ISP 270 are the same as those of the image sensor 1000 of FIG. 1.

In the image sensor 1000a of some example embodiments, the pixel area 100a may include the active pixel region APS and the optical black region Oba. The active pixel region APS is the same as that of the image sensor 1000 of FIG. 3. The optical black region Oba may include the first ARL 120-1, the metal layer 160, the spacer layer 130, the second MOE layer 140B, and the second ARL 120-2 above the pixel 110. The first ARL 120-1, the spacer layer 130, the second MOE layer 140B, and the second ARL 120-2 are the same as those of the image sensor 1000 of FIG. 3.

In the image sensor 1000a of some example embodiments, the metal layer 160 may be arranged on the first ARL 120-1 in the optical black region Oba of the pixel area 100a. The metal layer 160 may suppress light from entering the ADLC region ADLCA. As the second MOE layer 140B is arranged in the optical black region Oba of the image sensor 1000a of some example embodiments, the thickness of the metal layer 160 may be minimized or reduced. For example, in the image sensor 1000a of some example embodiments, the metal layer 160 may have a thickness of about or exactly 2000 Å or less (e.g., about or exactly 0 Å). However, the thickness of the metal layer 160 is not limited to the numerical range mentioned above. For example, the metal layer 160 may include W. However, the material of the metal layer 160 is not limited to W.

Although not shown, a barrier metal layer may be further arranged between the metal layer 160 and the first ARL 120-1 to increase the adhesive strength therebetween. For example, the barrier metal layer may include titanium (Ti) and/or titanium nitride (TiN).

In the image sensor 1000a of some example embodiments, the metal layer 160 may cover the whole of the optical black region OB. Accordingly, the metal layer 160 may also cover both the dummy region DMA and the drain region DRA together with the ADLC region ADLCA. In the image sensor 1000a of some example embodiments, together with the second MOE layer 140B, the metal layer 160 arranged in the optical black region Oba may further reduce light incident to the ADLC region ADLCA, thereby further increasing ADLC performance.

Referring to FIG. 7B, an image sensor 1000b of some example embodiments may be similar to the image sensor 1000a of FIG. 7A in that a metal layer 160a is provided in an optical black region Obb. However, the size of the metal layer 160a in the optical black region Obb of the image sensor 1000b of some example embodiments may be less than the size of the metal layer 160 in the optical black region Oba of the image sensor 1000a of FIG. 7A.

Specifically, in the image sensor 1000b of some example embodiments, a pixel area 100b may include the active pixel region APS and the optical black region Obb. The active pixel region APS is the same as that of the image sensor 1000 of FIG. 3. The optical black region Obb may include the first ARL 120-1, the metal layer 160a, the spacer layer 130, the second MOE layer 140B, and the second ARL 120-2 above the pixel 110. The first ARL 120-1, the spacer layer 130, the second MOE layer 140B, and the second ARL 120-2 are the same as those of the image sensor 1000 of FIG. 3.

In the image sensor 1000b of some example embodiments, the metal layer 160a of the optical black region Obb may cover only the ADLC region ADLCA and may not cover the dummy region DMA and the drain region DRA. In some example embodiments, the metal layer 160a of the optical black region Obb may cover the ADLC region ADLCA and a portion of the dummy region DMA adjacent to the ADLC region ADLCA.

In the image sensor 1000b of some example embodiments, the metal layer 160a may be arranged only in the ADLC region ADLCA of the optical black region Obb and may not be arranged in either the dummy region DMA or the drain region DRA in the optical black region Obb adjacent to the active pixel region APS. Accordingly, light reflection by a metal layer may not occur in a portion of the optical black region Obb adjacent to the active pixel region APS shown by crossed arrows CA. Consequently, a flare phenomenon may be minimized or reduced in the image sensor 1000b of some example embodiments.

Referring to FIG. 7C, an image sensor 1000c of some example embodiments may be different from the image sensor 1000 of FIG. 3 in that a second color filter layer 150B is further provided in an optical black region Obc. In the image sensor 1000c of some example embodiments, a pixel area 100c may include the active pixel region APS and the optical black region Obc. The active pixel region APS is the same as that of the image sensor 1000 of FIG. 3. The optical black region Obc may include the first ARL 120-1, the second color filter layer 150B, the spacer layer 130, the second MOE layer 140B, and the second ARL 120-2 above the pixel 110. The first ARL 120-1, the spacer layer 130, the second MOE layer 140B, and the second ARL 120-2 are the same as those in the optical black region OB of the image sensor 1000 of FIG. 3.

In the image sensor 1000c of some example embodiments, the second color filter layer 150B may be arranged on the first ARL 120-1 in the optical black region Obc of the pixel area 100c. The second color filter layer 150B may suppress light from entering the ADLC region ADLCA. Unlike the first color filter layer 150P of the active pixel region APS, the second color filter layer 150B of the optical black region Obc may include a single color filter. In addition, a grid pattern separating color filter from each other may not be arranged either. For example, in the image sensor 1000c of some example embodiments, the second color filter layer 150B may include a blue filter.

However, the second color filter layer 150B is not limited to the blue filter. In the image sensor 1000c of some example embodiments, the second color filter layer 150B may be formed together with the first color filter layer 150P of the active pixel region APS. Because a separate process of forming the second color filter layer 150B is unnecessary or optional, the second color filter layer 150B may be easily formed in the optical black region Obc.

In the image sensor 1000c of some example embodiments, together with the second MOE layer 140B, the second color filter layer 150B arranged in the optical black region Obc may reduce light incident to the ADLC region ADLCA, thereby increasing ADLC performance. In addition, because a metal layer is not arranged, a flare phenomenon may be reduced or prevented.

Referring to FIG. 7D, an image sensor 1000d of some example embodiments may be different from the image sensor 1000c of FIG. 7C in that the metal layer 160 is further provided in an optical black region Obd. Specifically, in the image sensor 1000d of some example embodiments, a pixel area 100d may include the active pixel region APS and the optical black region Obd. The active pixel region APS is the same as that of the image sensor 1000 of FIG. 3. The optical black region Obd may include the first ARL 120-1, the metal layer 160, the second color filter layer 150B, the spacer layer 130, the second MOE layer 140B, and the second ARL 120-2 above the pixel 110. The first ARL 120-1, the spacer layer 130, the second MOE layer 140B, and the second ARL 120-2 are the same as those in the optical black region OB of the image sensor 1000 of FIG. 3. The metal layer 160 is the same as the metal layer 160 of the image sensor 1000a of FIG. 7A, and the second color filter layer 150B is the same as the second color filter layer 150B of the image sensor 1000c of FIG. 7C.

In the image sensor 1000d of some example embodiments, together with the second MOE layer 140B, the metal layer 160 and second color filter layer 150B arranged in the optical black region Obd may further reduce light incident to the ADLC region ADLCA, thereby further increasing ADLC performance. The metal layer 160 may cover the whole of the optical black region Obd but is not limited thereto. As in the image sensor 1000b of FIG. 7B, the metal layer 160 may cover only a portion, e.g., the ADLC region ADLCA, of the optical black region Obd.

Referring to FIG. 7E, an image sensor 1000e of some example embodiments may be different from the image sensor 1000 of FIG. 3 in that a black photoresist (PR) layer 170 is further provided in an optical black region Obe. Specifically, in the image sensor 1000e of some example embodiments, a pixel area 100e may include the active pixel region APS and the optical black region Obe. The active pixel region APS is the same as that of the image sensor 1000 of FIG. 3. The optical black region Obe may include the first ARL 120-1, the black PR layer 170 (or BPR layer 170), the spacer layer 130, the second MOE layer 140B, and the second ARL 120-2 above the pixel 110. The first ARL 120-1, the spacer layer 130, the second MOE layer 140B, and the second ARL 120-2 are the same as those in the optical black region OB of the image sensor 1000 of FIG. 3.

In the image sensor 1000e of some example embodiments, the black PR layer 170 may be arranged on the first ARL 120-1 in the optical black region Obe of the pixel area 100e. The black PR layer 170 may suppress light from entering the ADLC region ADLCA. The black PR layer 170 may block light. The black PR layer 170 is usually used in a grid pattern that separates color filter from each other in a color filter layer and is referred to as a black matrix.

In the image sensor 1000e of some example embodiments, together with the second MOE layer 140B, the black PR layer 170 arranged in the optical black region Obe may reduce light incident to the ADLC region ADLCA, thereby increasing ADLC performance. In addition, because a metal layer is not arranged, a flare phenomenon may be reduced or prevented.

Referring to FIG. 7F, an image sensor 1000f of some example embodiments may be different from the image sensor 1000e of FIG. 7E in that the metal layer 160 is further provided in an optical black region Obf. Specifically, in the image sensor 1000f of some example embodiments, a pixel area 100f may include the active pixel region APS and the optical black region Obf. The active pixel region APS is the same as that of the image sensor 1000 of FIG. 3. The optical black region Obf may include the first ARL 120-1, the metal layer 160, the black PR layer 170, the spacer layer 130, the second MOE layer 140B, and the second ARL 120-2 above the pixel 110. The first ARL 120-1, the spacer layer 130, the second MOE layer 140B, and the second ARL 120-2 are the same as those in the optical black region OB of the image sensor 1000 of FIG. 3. The metal layer 160 is the same as the metal layer 160 of the image sensor 1000a of FIG. 7A, and the black PR layer 170 is the same as the black PR layer 170 of the image sensor 1000e of FIG. 7E.

In the image sensor 1000f of some example embodiments, together with the second MOE layer 140B, the metal layer 160 and the black PR layer 170, which are arranged in the optical black region Obf, may further reduce light incident to the ADLC region ADLCA, thereby further increasing ADLC performance. The metal layer 160 may cover the whole of the optical black region Obf but is not limited thereto. As in the image sensor 1000b of FIG. 7B, the metal layer 160 may cover only a portion, e.g., the ADLC region ADLCA, of the optical black region Obf.

Referring to FIG. 7G, an image sensor 1000g of some example embodiments may be different from the image sensor 1000 of FIG. 3 in that an MOE layer 140a has a multi-layer structure in a pixel area 100g. Specifically, the image sensor 1000g may include the pixel area 100g, the row driver 220, the mode set register 230, the timing controller 240, the ramp signal generator 250, the ADC block 260, and the ISP 270. The row driver 220, the mode set register 230, the timing controller 240, the ramp signal generator 250, the ADC block 260, and the ISP 270 are the same as those of the image sensor 1000 of FIG. 1. Except for the MOE layer 140a, the other components of the pixel area 100g are the same as those in the pixel area 100 of the image sensor 1000 of FIG. 3.

In the image sensor 1000g of some example embodiments, the pixel area 100g may include the MOE layer 140a having a multi-layer structure. For example, in the image sensor 1000g of some example embodiments, the MOE layer 140a may include a triple-layer structure. However, the MOE layer 140a is not limited to a triple-layer structure. For example, the MOE layer 140a may have a double-layer structure or a quadruple-layer structure or more. The MOE layer 140a may be divided into a first MOE layer 140Pa in an active pixel region APSa and a second MOE layer 140Ba in an optical black region Obg.

The MOE layer 140a may include a first layer 140-1, a second layer 140-2, and a third layer 140-3. The first layer 140-1, the second layer 140-2, and the third layer 140-3 may be sequentially stacked from the bottom to the top. Accordingly, light incident to the pixel area 100g may first pass through the third layer 140-3, then the second layer 140-2, and finally the first layer 140-1. The first layer 140-1, the second layer 140-2, and the third layer 140-3 may have almost the same thickness. However, in some example embodiments, at least one of the first layer 140-1, the second layer 140-2, and the third layer 140-3 may have a different thickness.

Each of the first layer 140-1, the second layer 140-2, and the third layer 140-3 may include a nano-post 142 having a high refractive index and a dielectric layer 144 having a lower refractive index. The first layer 140-1, the second layer 140-2, and the third layer 140-3 may have different pattern structures from one another. In other words, a pattern structure formed by nano-posts 142 may be different among the first layer 140-1, the second layer 140-2, and the third layer 140-3. As described above, the pattern structure may refer to the size, shape, spacing, and/or arrangement of the nano-posts 142.

In the image sensor 1000g of some example embodiments, the first layer 140-1, the second layer 140-2, and the third layer 140-3 of the MOE layer 140a may play the same role, or at least one of the first to third layers 140-1 to 140-3 may play a different role. For example, in the active pixel region APSa, the first layer 140-1, the second layer 140-2, and the third layer 140-3 may all focus light like microlenses. In the active pixel region APSa, the first layer 140-1 may split light by wavelength, and the second layer 140-2 and the third layer 140-3 may focus light. The first layer 140-1 may split light by wavelength, the second layer 140-2 may correct aberration, and the third layer 140-3 may focus light.

As shown in FIG. 7G, in the MOE layer 140a having a multi-layer structure, an etch stop layer 145 may be between the first layer 140-1 and the second layer 140-2 and between the second layer 140-2 and the third layer 140-3. The etch stop layer 145 may protect a lower layer in a process of forming the nano-posts 142 of an upper layer. The etch stop layer 145 may include a transparent dielectric material having a high etch selectivity with respect to the dielectric layer 144. For example, the etch stop layer 145 may include at least one selected from the group consisting of aluminum oxide (Al₂O₃), hafnium oxide (HfO₂), and silicon nitride (SiNₓ). The etch stop layer 145 may have a thickness capable of protecting a lower layer without impairing the optical characteristics of the MOE layer 140a. For example, the etch stop layer 145 may have a thickness of about or exactly 3 nm to about or exactly 50 nm. However, the thickness of the etch stop layer 145 is not limited to the numerical range mentioned above.

Because the MOE layer 140a having a multi-layer structure is formed in the pixel area 100g of the image sensor 1000g of some example embodiments, various optical characteristics may be implemented through the MOE layer 140a. In addition, because deflection of light is enhanced by the MOE layer 140a having a multi-layer structure in the optical black region Obg, light incident to the ADLC region ADLCA may be further decreased, and thus, ADLC performance may be further increased.

FIGS. 8A to 8E are cross-sectional views each illustrating an active pixel region and an optical black region in each of image sensors according to some example embodiments. FIGS. 1 to 3 are also referred to, and redundant descriptions given above with reference to FIGS. 1 to 7G are brief or omitted.

Referring to FIG. 8A, an image sensor 1000h of some example embodiments may be different from the image sensor 1000 of FIG. 3 in the structure of a first MOE layer 140Pb of an active pixel region APSb. Specifically, the image sensor 1000h may include a pixel area 100h, the row driver 220, the mode set register 230, the timing controller 240, the ramp signal generator 250, the ADC block 260, and the ISP 270. The row driver 220, the mode set register 230, the timing controller 240, the ramp signal generator 250, the ADC block 260, and the ISP 270 are the same as those of the image sensor 1000 of FIG. 1.

The pixel area 100h may include the active pixel region APSb and the optical black region OB. The optical black region OB is the same as that of the image sensor 1000 of FIG. 3. Except for the first MOE layer 140Pb, the other components of the active pixel region APSb are the same as those of the active pixel region APS of the image sensor 1000 of FIG. 3.

In the image sensor 1000h of some example embodiments, the first MOE layer 140Pb of the active pixel region APSb may focus light and correct aberration like an aberration-correcting lens. To focus light and correct aberration, the pattern structure of the first MOE layer 140Pb may be adjusted. In other words, the size, shape, spacing, and/or arrangement of the nano-posts 142 of the first MOE layer 140Pb may be adjusted to simultaneously focus light and correct aberration.

Because the image sensor 1000h of some example embodiments corrects aberration through the first MOE layer 140Pb, phase-detection auto-focus (PDAF) performance may be increased from the center to the edge of a chip. Accordingly, a signal difference between channels may be reduced. Consequently, the quality of image signals may be increased.

Referring to FIG. 8B, an image sensor 1000i of some example embodiments may be different from the image sensor 1000 of FIG. 3 in the structure of a first MOE layer 140Pc of an active pixel region APSc and in that a color filter layer is omitted from the active pixel region APSc. Specifically, in the image sensor 1000i of some example embodiments, a pixel area 100i may include the active pixel region APSc and the optical black region OB. The optical black region OB is the same as that of the image sensor 1000 of FIG. 3. Except for the first MOE layer 140Pc and a color filter layer, the other components of the active pixel region APSc are the same as those of the active pixel region APS of the image sensor 1000 of FIG. 3.

In the pixel area 100i of the image sensor 1000i of some example embodiments, the first MOE layer 140Pc of the active pixel region APSc may focus light and function as a color filter that splits light by wavelength as seen by the little arrows LA. Because the first MOE layer 140Pc functions as a color filter, a color filter layer may be omitted from the active pixel region APSc. To give a specific example, when the color filters of the first color filter layer 150P of the image sensor 1000 of FIG. 3 have an RGB bayer pattern, the first MOE layer 140Pc may split incident light into green light, blue light, and red light and focus green light to first and fourth pixels corresponding to green filters, blue light to a second pixel corresponding to a blue filter, and red light to a third pixel corresponding to a red filter. The pattern structure of the first MOE layer 140Pc may be adjusted to focus light by wavelength. In other words, the size, shape, spacing, and/or arrangement of the nano-posts 142 of the first MOE layer 140Pc may be adjusted to simultaneously focus light and function as a color filter.

Referring to FIG. 8C, an image sensor 1000j of some example embodiments may be different from the image sensor 1000i of FIG. 8B in the structure of a first MOE layer 140Pd of an active pixel region APSd. Specifically, in the image sensor 1000j of some example embodiments, a pixel area 100j may include the active pixel region APSd and the optical black region OB. The optical black region OB is the same as that of the image sensor 1000 of FIG. 3. Except for the first MOE layer 140Pd, the other components of the active pixel region APSd are the same as those of the active pixel region APSc of the image sensor 1000i of FIG. 8B.

In the pixel area 100j of the image sensor 1000j of some example embodiments, the first MOE layer 140Pd of the active pixel region APSd may focus light and function as a color filter that splits light by wavelength. The first MOE layer 140Pd may also function as an infrared (IR) filter (or color infrared filter) that separates IR wavelengths from light. Because the first MOE layer 140Pd functions as a color filter, a color filter layer may be omitted from the active pixel region APSd. The pattern structure of the first MOE layer 140Pd may be adjusted to focus light by wavelength, including IR wavelengths. In other words, the size, shape, spacing, and/or arrangement of the nano-posts 142 of the first MOE layer 140Pd may be adjusted to simultaneously focus light and function as a color filter and an IR filter.

Referring to FIG. 8D, an image sensor 1000k of some example embodiments may be different from the image sensor 1000i of FIG. 8B in the structure of a first MOE layer 140Pe of an active pixel region APSe. Specifically, in the image sensor 1000k of some example embodiments, a pixel area 100k may include the active pixel region APSe and the optical black region OB. The optical black region OB is the same as that of the image sensor 1000 of FIG. 3. Except for the first MOE layer 140Pe, the other components of the active pixel region APSe are the same as those of the active pixel region APSc of the image sensor 1000i of FIG. 8B.

In the pixel area 100k of the image sensor 1000k of some example embodiments, the first MOE layer 140Pe of the active pixel region APSe may focus light and function as an IR filter that separates IR wavelengths. Because the image sensor 1000k of some example embodiments blocks visible light and receives only light of IR wavelengths through the first MOE layer 140Pe, a color filter layer may be omitted from the active pixel region APSe. The pattern structure of the first MOE layer 140Pe may be adjusted to separate IR wavelengths from light and focus the IR wavelengths. In other words, the size, shape, spacing, and/or arrangement of the nano-posts 142 of the first MOE layer 140Pe may be adjusted to simultaneously focus light and function as an IR filter.

Referring to FIG. 8E, an image sensor 1000l of some example embodiments may be different from the image sensor 1000i of FIG. 8B in the structure of a first MOE layer 140Pf of an active pixel region APSf. Specifically, in the image sensor 1000l of some example embodiments, a pixel area 100l may include the active pixel region APSf and the optical black region OB. The optical black region OB is the same as that of the image sensor 1000 of FIG. 3. Except for the first MOE layer 140Pf, the other components of the active pixel region APSf are the same as those of the active pixel region APSc of the image sensor 1000i of FIG. 8B.

In the pixel area 100l of the image sensor 1000l of some example embodiments, the first MOE layer 140Pf of the active pixel region APSf may focus light and function as a polarizing filter that separates polarization of light. In the image sensor 1000l of some example embodiments, the first MOE layer 140Pf may function as a color polarizing filter. Accordingly, a color filter layer may be omitted from the active pixel region APSf. However, in some example embodiments, the first MOE layer 140Pf may only separate a polarization state. In this case, a color filter layer may be arranged in the active pixel region APSf. The pattern structure of the first MOE layer 140Pf may be adjusted to separate and focus light having the polarization state. In other words, the size, shape, spacing, and/or arrangement of the nano-posts 142 of the first MOE layer 140Pf may be adjusted to simultaneously focus light and function as a polarizing filter. The image sensor 1000l of some example embodiments may route light according to polarization, thereby implementing a polarizing sensor having a QE of at least 50% (for example, a QE of 50% to 75%).

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to some example embodiments thereof, it will be understood that various changes in form and details may be made therein without departing from the spirit and scope of the following claims.

What is claimed is:

1. An image sensor comprising:
a substrate comprising an active pixel region and an optical black (OB) region outside the active pixel region, the active pixel region comprising a plurality of active pixels arranged in a two-dimensional array structure;
a photoelectric conversion element (PD) in the active pixel region and the OB region of the substrate;
a spacer layer on the PD; and
a meta-optical element (MOE) layer on the spacer layer,
the OB region including an auto dark level compensation (ADLC) region.

2. The image sensor of claim 1, wherein the OB region includes a drain region and a dummy region around the ADLC region.

3. The image sensor of claim 1, wherein
the MOE layer includes a plurality of nano-posts and
a dielectric layer between the plurality of nano-posts, the dielectric layer having a lower refractive index than the plurality of nano-posts.

4. The image sensor of claim 3, wherein
the OB region includes a dummy region, a drain region, and the ADLC region, the dummy region and the drain region being respectively at opposite sides of the ADLC region in a first direction,
the plurality of nano-posts each have a cylindrical shape,
diameters of the plurality of nano-posts increase in the ADLC region toward the drain region in the first direction, and
the diameters of the plurality of nano-posts decrease in the drain region toward opposite outer sides of the drain region in the first direction.

5. The image sensor of claim 1, wherein the MOE layer has a multi-layer structure.

6. The image sensor of claim 5, wherein
layers in the multi-layer structure have different patterns and thicknesses from each other, and
an etch stop layer is between adjacent layers in the multi-layer structure.

7. The image sensor of claim 1, wherein the OB region includes a layered structure selected from:
a first structure including the PD, a first anti-reflection layer (ARL), the spacer layer, the MOE layer, and a second ARL;
a second structure including the PD, the first ARL, a metal layer, the spacer layer, the MOE layer, and the second ARL;
a third structure including the PD, the first ARL, a color filter layer, the spacer layer, the MOE layer, and the second ARL;
a fourth structure including the PD, the first ARL, the metal layer, the color filter layer, the spacer layer, the MOE layer, and the second ARL;
a fifth structure including the PD, the first ARL, a black photoresist (BPR) layer, the spacer layer, the MOE layer, and the second ARL;
a sixth structure including the PD, the first ARL, the metal layer, the BPR layer, the spacer layer, the MOE layer, and the second ARL; and
a seventh structure including the PD, the first ARL, the spacer layer, the MOE layer having multiple layers, and the second ARL.

8. The image sensor of claim 7, wherein
the OB region includes a drain region and a dummy region around the ADLC region,
the OB region has a structure including the metal layer on the first ARL, and
the metal layer covers all of the OB region or covers the ADLC region.

9. The image sensor of claim 1, wherein the active pixel region has a layered structure selected from:
a first structure including the PD, a first anti-reflection layer (ARL), a color filter layer, the spacer layer, the MOE layer, and the second ARL;
a second structure including the PD, the first ARL, the spacer layer, the MOE layer, and a second ARL; and
a third structure including the PD, the first ARL, the spacer layer, the MOE layer having multiple layers, and the second ARL.

10. The image sensor of claim 9, wherein
the active pixel region has the second structure, and
the MOE layer in the active pixel region includes at least one selected from the group consisting of an aberration-correcting lens, a color filter, a color infrared (IR) filter, an IR filter, and a polarizing filter.

11. An image sensor comprising:
a substrate comprising an active pixel region and an optical black (OB) region outside the active pixel region, the active pixel region comprising a plurality of active pixels arranged in a two-dimensional array structure;
a photoelectric conversion element (PD) in the active pixel region and the OB region of the substrate;
a spacer layer on the PD; and
a meta-optical element (MOE) layer on the spacer layer and including a plurality of nano-posts and a dielectric layer arranged between the plurality of nano-posts,
the OB region including a dummy region, a drain region, and an auto dark level compensation (ADLC) region, the dummy region and the drain region being respectively at opposite sides of the ADLC region in a first direction.

12. The image sensor of claim 11, wherein
the plurality of nano-posts each have a cylindrical shape,
diameters of the plurality of nano-posts increase in the ADLC region toward the drain region in the first direction, and
the diameters of the plurality of nano-posts decrease in the drain region toward opposite outer sides of the drain region in the first direction.

13. The image sensor of claim 11, wherein
the MOE layer has a multi-layer structure, and
layers in the multi-layer structure have different patterns from each other.

14. The image sensor of claim 11, wherein the OB region includes a layered structure selected from:
a first structure including the PD, a first anti-reflection layer (ARL), the spacer layer, the MOE layer, and a second ARL;
a second structure including the PD, the first ARL, a metal layer, the spacer layer, the MOE layer, and the second ARL;
a third structure including the PD, the first ARL, a color filter layer, the spacer layer, the MOE layer, and the second ARL;
a fourth structure including the PD, the first ARL, the metal layer, the color filter layer, the spacer layer, the MOE layer, and the second ARL;
a fifth structure including the PD, the first ARL, a black photoresist (BPR) layer, the spacer layer, the MOE layer, and the second ARL;
a sixth structure including the PD, the first ARL, the metal layer, the BPR layer, the spacer layer, the MOE layer, and the second ARL; and
a seventh structure including the PD, the first ARL, the spacer layer, the MOE layer having multiple layers, and the second ARL.

15. The image sensor of claim 11, wherein
the active pixel region has a layered structure selected from:
a first structure including the PD, the first ARL, a color filter layer, the spacer layer, the MOE layer, and the second ARL;
a second structure including the PD, the first ARL, the spacer layer, the MOE layer, and the second ARL; and
a third structure including the PD, the first ARL, the spacer layer, the MOE layer having multiple layers, and the second ARL, and
the MOE layer in the second structure includes at least one selected from the group consisting of an aberration-correcting lens, a color filter, a color infrared (IR) filter, an IR filter, and a polarizing filter.

16. An image sensor comprising:
A first semiconductor chip including a first substrate and a first wiring layer below the first substrate, the first substrate comprising an active pixel region and an optical black (OB) region outside the active pixel region, and the active pixel region comprising a plurality of active pixels are arranged in a two-dimensional array structure; and
a second semiconductor chip coupled to the first semiconductor chip, the second semiconductor chip including a second substrate and a second wiring layer on the second substrate, the second substrate comprising a logic area including logic devices,
the first semiconductor chip including
a photoelectric conversion element (PD) in the active pixel region and the OB region of the substrate,
a spacer layer on the PD, and
a meta-optical element (MOE) layer on the spacer layer, and
the OB region including an auto dark level compensation (ADLC) region.

17. The image sensor of claim 16, wherein
the MOE layer includes a plurality of nano-posts and a dielectric layer arranged between the plurality of nano-posts, and
the OB region includes a dummy region, a drain region, and the ADLC region, the dummy region and the drain region being respectively at opposite sides of the ADLC region in a first direction.

18. The image sensor of claim 17, wherein
the plurality of nano-posts each have a cylindrical shape,
diameters of the plurality of nano-posts increase in the ADLC region toward the drain region in the first direction, and
the diameters of the plurality of nano-posts decrease in the drain region toward opposite outer sides of the drain region in the first direction.

19. The image sensor of claim 16, wherein the OB region includes a layered structure selected from:
a first structure including the PD, a first anti-reflection layer (ARL), the spacer layer, the MOE layer, and a second ARL;
a second structure including the PD, the first ARL, a metal layer, the spacer layer, the MOE layer, and the second ARL;
a third structure including the PD, the first ARL, a color filter layer, the spacer layer, the MOE layer, and the second ARL;
a fourth structure including the PD, the first ARL, the metal layer, the color filter layer, the spacer layer, the MOE layer, and the second ARL;
a fifth structure including the PD, the first ARL, a black photoresist (BPR) layer, the spacer layer, the MOE layer, and the second ARL;
a sixth structure including the PD, the first ARL, the metal layer, the BPR layer, the spacer layer, the MOE layer, and the second ARL; and
a seventh structure including the PD, the first ARL, the spacer layer, the MOE layer having multiple layers, and the second ARL.

20. The image sensor of claim 16, wherein
the active pixel region has a layered structure selected from:
a first structure including the PD, a first anti-reflection layer (ARL), a color filter layer, the spacer layer, the MOE layer, and a second ARL;
a second structure including the PD, the first ARL, the spacer layer, the MOE layer, and the second ARL; and
a third structure including the PD, the first ARL, the spacer layer, the MOE layer having multiple layers, and the second ARL, and
the MOE layer in the second structure includes at least one selected from the group consisting of an aberration-correcting lens, a color filter, a color infrared (IR) filter, an IR filter, and a polarizing filter.
